(19) United States
(12) Patent Application Publication
(10) Pub. No.: US 2026/0265949 A1
(43) Pub. Date: Sep. 10, 2026

(54) FILM FORMING METHOD AND FILM FORMING APPARATUS

(71) Applicant: Tokyo Electron Limited, Tokyo (JP)

(72) Inventors: Tetsuji UENO, Yamanashi (JP); Tomoya HASEGAWA, Yamanashi (JP); Shuntaro TAKAHASHI, Yamanashi (JP); Yuki TANABE, Yamanashi (JP); Junki MATSUMOTO, Yamanashi (JP)

(21) Appl. No.: 19/543,202

(22) Filed: Feb. 18, 2026

(30) Foreign Application Priority Data
Mar. 4, 2025 (JP) 2025-033762

(51) Int. Cl. C30B 25/10; C23C 16/02; C23C 16/06; C23C 16/24; C23C 16/46; C23C 16/52; C30B 25/16; C30B 25/18; C30B 29/06; C30B 29/52; C30B 29/68; H10P 14/20; H10P 14/24

(52) U.S. Cl. CPC C30B 25/10; C23C 16/0227; C23C 16/06; C23C 16/24; C23C 16/46; C23C 16/52; C30B 25/16; C30B 25/186; C30B 29/06; C30B 29/52; C30B 29/68; H10P 14/24; H10P 14/3211; H10P 14/3248; H10P 14/3411; H10P 14/3602

(57) ABSTRACT

A film forming method includes: forming a silicon germanium film on a substrate by supplying a first silicon-containing gas and a germanium-containing gas to the substrate while heating the substrate at a first temperature; forming a first silicon film on the silicon germanium film by supplying a second silicon-containing gas to the substrate while heating the substrate at the first temperature; increasing a temperature of the substrate from the first temperature to a second temperature higher than the first temperature; and forming a second silicon film on the first silicon film by supplying a third silicon-containing gas to the substrate while heating the substrate at the second temperature.

### CROSS-REFERENCE TO RELATED APPLICATIONS

This application is based on and claims priority to Japanese Patent Application No. 2025-033762, filed on Mar. 4, 2025, the entire contents of which are incorporated herein by reference.

### TECHNICAL FIELD

The present disclosure relates to a film forming method and a film forming apparatus.

### BACKGROUND ART

Japanese Patent No. 6777624 describes that a silicon germanium film is formed on a substrate at a first temperature first, after which the temperature is increased from the first temperature to a second temperature, and then a silicon film is formed on the silicon germanium film at the second temperature.

### SUMMARY

A film forming method according to one aspect of the present disclosure includes: forming a silicon germanium film on a substrate by supplying a first silicon-containing gas and a germanium-containing gas to the substrate while heating the substrate at a first temperature; forming a first silicon film on the silicon germanium film by supplying a second silicon-containing gas to the substrate while heating the substrate at the first temperature; increasing a temperature of the substrate from the first temperature to a second temperature higher than the first temperature; and forming a second silicon film on the first silicon film by supplying a third silicon-containing gas to the substrate while heating the substrate at the second temperature.

### BRIEF DESCRIPTION OF THE DRAWINGS

FIG. 1 is a flowchart illustrating a film forming method according to an embodiment;

FIG. 2 is a graph illustrating a substrate temperature in the film forming method according to the embodiment;

FIG. 3 is a cross-sectional view (1) illustrating the film forming method according to the embodiment;

FIG. 4 is a cross-sectional view (2) illustrating the film forming method according to the embodiment;

FIG. 5 is a cross-sectional view (3) illustrating the film forming method according to the embodiment;

FIG. 6 is a cross-sectional view (4) illustrating the film forming method according to the embodiment;

FIG. 7 is a cross-sectional view (5) illustrating the film forming method according to the embodiment;

FIG. 8 is a schematic cross-sectional view illustrating a film forming apparatus according to an embodiment;

FIG. 9 is a diagram illustrating results of an example; and

FIG. 10 is a diagram illustrating results of a comparative example.

### DETAILED DESCRIPTION

Non-limiting exemplary embodiments of the present disclosure will be described below with reference to the accompanying drawings. In all of the accompanying drawings, the same or corresponding members or parts are denoted by the same or corresponding reference numerals, and duplicated descriptions will be omitted.

### Segregation of Germanium Ge

In a case where a silicon (Si) film is formed on a silicon germanium (SiGe) film at a temperature higher than a temperature at which the silicon germanium film is formed, the silicon film is formed after the temperature of a substrate is stabilized at the film forming temperature of the silicon film following the formation of the silicon germanium film. For this reason, after the silicon germanium film is formed, the silicon germanium film is heated with the outermost surface of the silicon germanium film exposed until the temperature of the substrate is stabilized at the film forming temperature of the silicon film. Because germanium atoms are larger than silicon atoms, the surface of the silicon-germanium film is more stable than the interior of the silicon-germanium film. Therefore, germanium in the silicon germanium film segregates to the outermost surface. As a result, the sharpness of the profile of germanium at the interface between the silicon germanium film and the silicon film deteriorates.

Hereinafter, a film forming method that can suppress segregation of germanium when a silicon film is formed on a silicon germanium film will be described.

### Film Forming Method

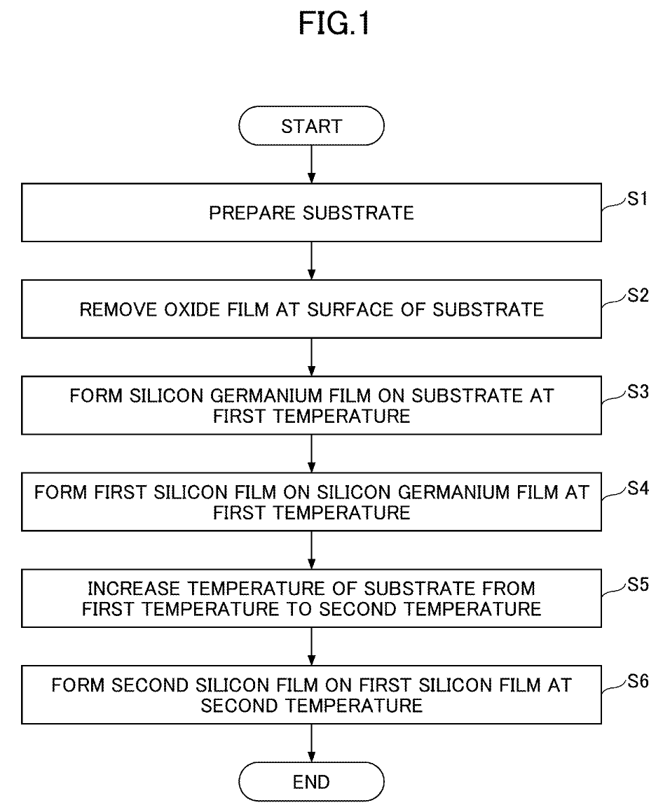

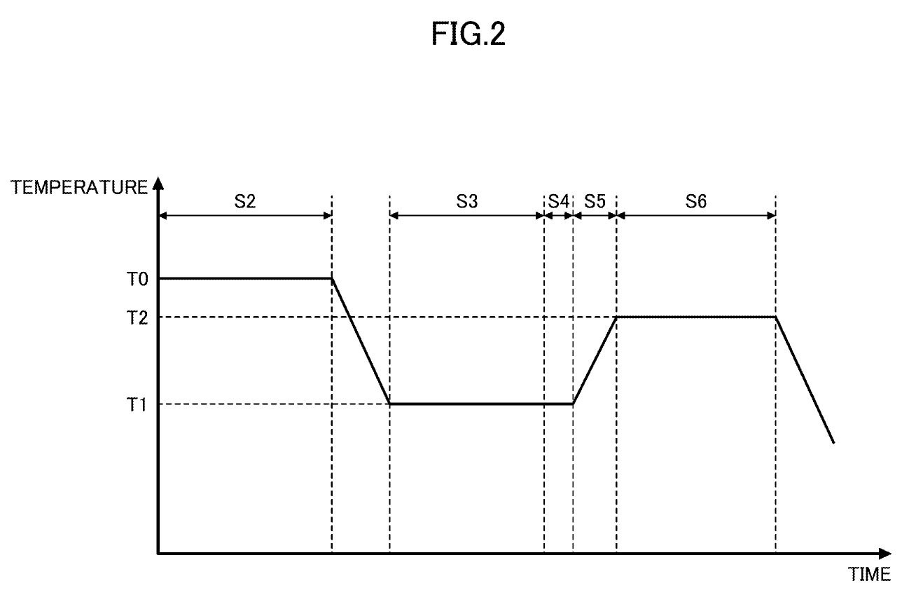

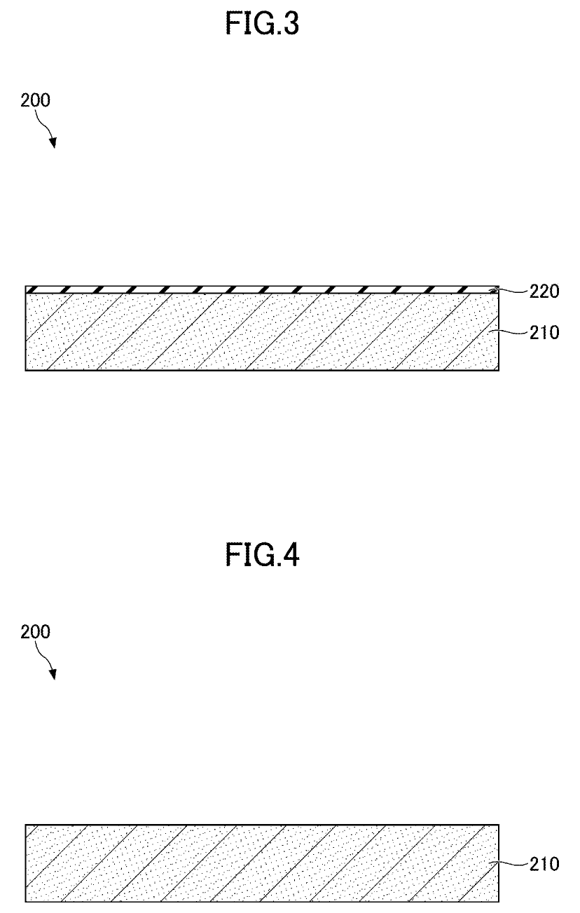

A film forming method according to an embodiment will be described with reference to FIG. 1 to FIG. 7. FIG. 1 is a flowchart illustrating the film forming method according to the embodiment. FIG. 2 is a graph illustrating a substrate temperature in the film forming method according to the embodiment. FIG. 3 to FIG. 7 are cross-sectional views illustrating the film forming method according to the embodiment. The film forming method according to the embodiment includes step S1 to step S6 illustrated in FIG. 1.

In step S1, as illustrated in FIG. 3, a substrate 200 is prepared. The substrate 200 includes a base substrate 210. The base substrate 210 is, for example, a silicon substrate. The base substrate 210 can include a native oxide film 220 resulting from surface oxidation.

In step S2, as illustrated in FIG. 4, the native oxide film 220 on the surface of the base substrate 210 is removed. For example, as illustrated in FIG. 2, the native oxide film 220 is removed by supplying a reducing gas to the substrate 200 while heating the substrate 200 at a heat treatment temperature T0, and by reducing the native oxide film 220 with the reducing gas. The reducing gas is, for example, hydrogen (H₂) gas. The heat treatment temperature T0 is a temperature at which a reduction reaction of the native oxide film 220 by the reducing gas is likely to occur, and is, for example, in a range of 800ºC or higher and 900ºC or lower. The heat treatment temperature is an example of a third temperature. The method of removing the native oxide film 220 is not limited to the above. The native oxide film 220 may be removed by a chemical oxide removal (COR) process. In the COR process, first, a fluorine-containing gas and a basic gas are supplied to the substrate 200 while heating the substrate 200 at a predetermined temperature (for example, 65°C), and the fluorine-containing gas and the basic gas are reacted with the native oxide film 220, thereby forming ammonium fluorosilicate. Subsequently, the substrate 200 is heated to a predetermined temperature (for example, 200°C) to sublimate the ammonium fluorosilicate, thereby removing the native oxide film 220. If the native oxide film 220 is not present on the surface of the base substrate 210, step S2 may be omitted. After step S2, as illustrated in FIG. 2, the temperature of the substrate 200 is decreased to a first temperature T1, which will be described below.

In step S3, as illustrated in FIG. 5, a silicon germanium film 230 is formed on the surface of the base substrate 210 from which the native oxide film 220 is removed. For example, as illustrated in FIG. 2, a first silicon-containing gas and a germanium-containing gas are supplied to the substrate 200 while heating the substrate 200 at the first temperature T1, and the silicon germanium film 230 is formed on the base substrate 210 by epitaxial growth. The first silicon-containing gas is, for example, monosilane (SiH₄) gas. The germanium-containing gas is, for example, monogermane (GeH₄) gas. The first temperature T1 is, for example, in a range of 400°C or higher and 600°C or lower. When the first temperature T1 is 400°C or higher, defects are less likely to occur in the silicon germanium film 230. When the first temperature T1 is 600°C or lower, germanium is less likely to segregate on the surface of the silicon germanium film 230 during formation of the silicon germanium film 230. Hydrogen chloride (HCl) gas may be added to the first silicon-containing gas and the germanium-containing gas when the silicon germanium film 230 is formed. In this case, the in-plane uniformity of the thickness of the silicon germanium film 230 formed on the substrate 200 is improved. Further, in a case where a silicon oxide film and a silicon film are formed on the surface of the base substrate 210, the silicon germanium film 230 can be formed selectively on the silicon film with respect to the silicon oxide film. The silicon germanium film 230 may contain carbon (C). For example, the silicon germanium film 230 containing carbon can be formed by adding a carbon-containing gas to the first silicon-containing gas and the germanium-containing gas. The carbon-containing gas is, for example, monomethylsilane (Si(CH₃) H₃) gas. The carbon-containing gas may be CₓH_{y} gas (x and y are integers greater than or equal to 1). Examples of the CₓH_{y} gas include ethylene (C₂H₄) gas and propane (C₃H₈) gas.

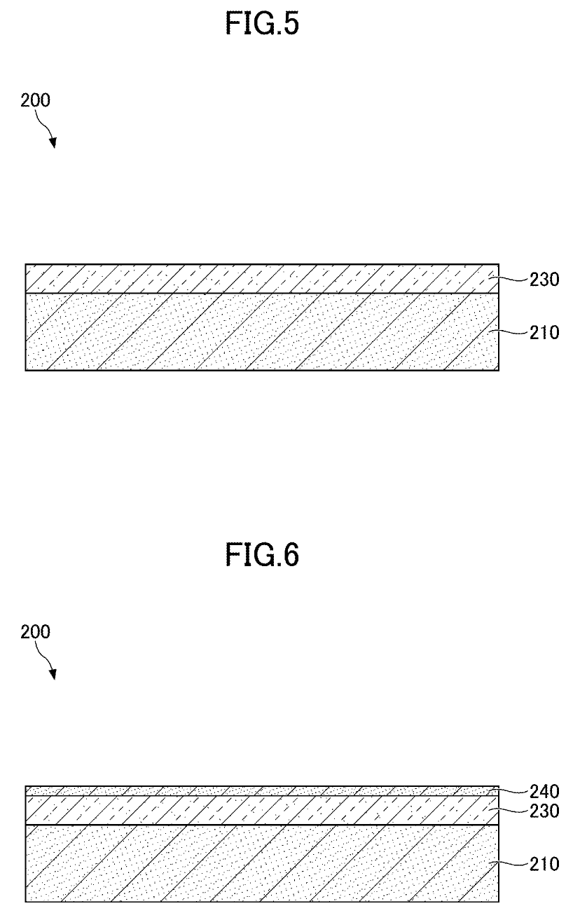

In step S4, as illustrated in FIG. 6, a first silicon film 240 is formed on the silicon germanium film 230. For example, as illustrated in FIG. 2, a second silicon-containing gas is supplied to the substrate 200 while heating the substrate 200 at the first temperature T1, and the first silicon film 240 is formed on the silicon germanium film 230 by epitaxial growth. In other words, the second silicon-containing gas is supplied to the substrate 200 while the temperature of the substrate 200 is maintained at the first temperature T1, which is the same as the temperature of the substrate 200 in step S3, and the first silicon film 240 is formed on the silicon germanium film 230 by epitaxial growth. The second silicon-containing gas may be the same as the first silicon-containing gas, and is, for example, monosilane gas. The first silicon film 240 formed at the first temperature T1 has a lower film formation rate and lower crystallinity than a second silicon film 250 formed at a second temperature T2, which will be described below. Therefore, the thickness of the first silicon film 240 is preferably small, and is, for example, 1 nm or less.

In step S5, as illustrated in FIG. 2, the temperature of the substrate 200 is increased from the first temperature T1 to the second temperature T2. At this time, the surface of the silicon germanium film 230 is covered by the first silicon film 240. The first silicon film 240 inhibits germanium in the silicon germanium film 230 from segregating to the outermost surface of the silicon germanium film 230. Therefore, segregation of germanium in the silicon germanium film 230 to the outermost surface can be suppressed. The second temperature T2 is higher than the first temperature T1, and is, for example, in a range of 600°C or higher and 700°C or lower.

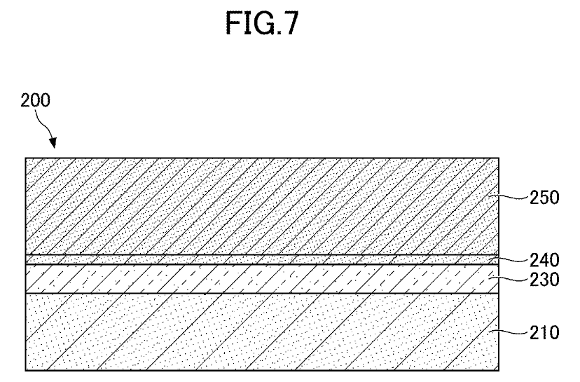

In step S6, as illustrated in FIG. 7, the second silicon film 250 is formed on the first silicon film 240. For example, as illustrated in FIG. 2, a third silicon-containing gas is supplied to the substrate 200 while heating the substrate 200 at the second temperature T2, and the second silicon film 250 is formed on the first silicon film 240 by epitaxial growth. By forming the second silicon film 250 at the second temperature T2 higher than the first temperature T1, the second silicon film 250 having high crystallinity can be formed at a high throughput. The third silicon-containing gas may be the same as the first silicon-containing gas, and is, for example, monosilane gas.

As described above, according to the film forming method according to the embodiment, first, in step S3, the silicon germanium film 230 is formed on the substrate 200 while heating the substrate 200 at the first temperature T1. Next, in step S4, the first silicon film 240 is formed on the silicon germanium film 230 while maintaining the substrate 200 at the first temperature T1. Next, in step S5, the temperature of the substrate 200 is increased from the first temperature T1 to the second temperature T2. In step S6, the second silicon film 250 is formed on the first silicon film 240 while heating the substrate 200 at the second temperature T2. In this case, when the temperature of the substrate 200 is increased from the first temperature T1 to the second temperature T2, the surface of the silicon germanium film 230 is covered by the first silicon film 240. The first silicon film 240 inhibits germanium in the silicon germanium film 230 from segregating to the outermost surface of the silicon germanium film 230. Therefore, segregation of germanium when the temperature of the substrate 200 is increased from the first temperature T1 to the second temperature T2 can be suppressed. That is, segregation of germanium when the silicon films (the first silicon film 240 and the second silicon film 250) are formed on the silicon germanium film 230 can be suppressed.

In the above-described embodiment, an example in which step S3, step S4, step S5, and step S6 are performed once in this order has been described; however, the present disclosure is not limited thereto. For example, step S3, step S4, step S5, and step S6 may be repeated a plurality of times in this order. Accordingly, a stacked film, in which the silicon germanium film 230 and the silicon films (the first silicon film 240 and the second silicon film 250) are alternately formed a plurality of times, can be formed on the base substrate 210.

### Film Forming Apparatus

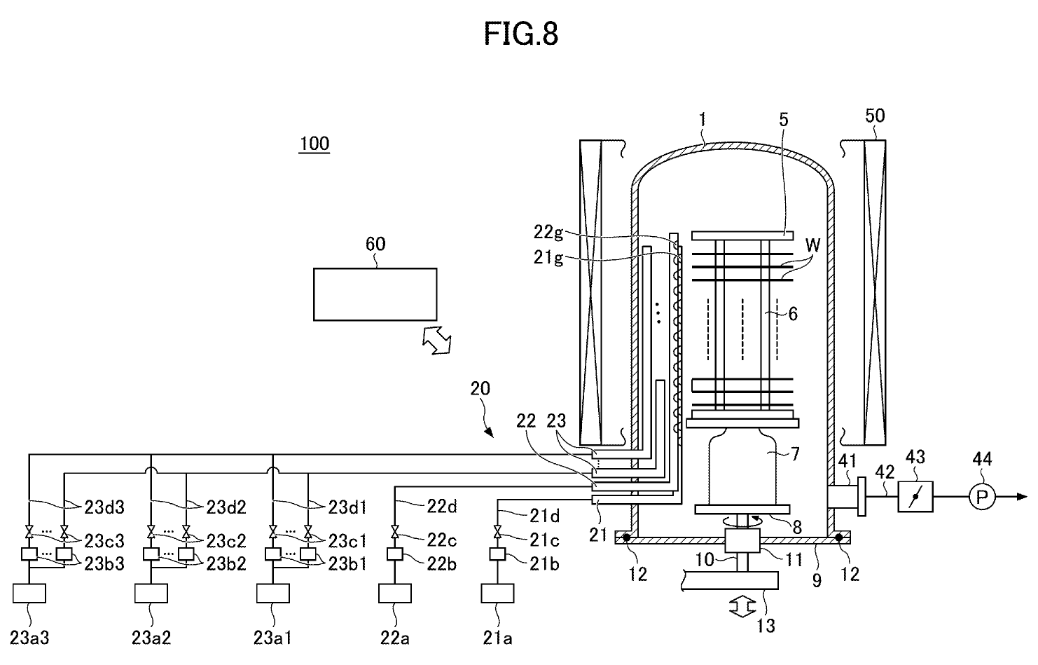

A film forming apparatus 100 according to an embodiment will be described with reference to FIG. 8. FIG. 8 is a schematic cross-sectional view illustrating the film forming apparatus 100 according to the embodiment.

The film forming apparatus 100 includes a processing chamber 1. The processing chamber 1 has a cylindrical shape with a ceiling and an open lower end. The entire processing chamber 1 is formed of, for example, quartz.

A boat 5 in which a plurality of (for example, 25 to 150) substrates W are arranged in multiple stages is inserted into the processing chamber 1 from below the processing chamber 1. Each of the substrates W is, for example, the above-described substrate 200. The plurality of substrates W are substantially horizontally accommodated in the processing chamber 1 at intervals in the vertical direction. The boat 5 is formed of, for example, quartz. The boat 5 includes three rods 6 (two of which are illustrated in FIG. 8), and the plurality of substrates W are supported by grooves (not illustrated) formed in the rods 6.

The boat 5 is placed on a table 8 via a heat insulation cylinder 7 formed of quartz. The table 8 is supported on a rotary shaft 10. The rotary shaft 10 penetrates a lid 9. The lid 9 opens and closes an opening at the lower end of the processing chamber 1. The lid 9 is formed of a metal such as stainless steel.

A magnetic fluid seal 11 is provided at the penetrating portion of the rotary shaft 10. The magnetic fluid seal 11 airtightly seals and rotatably supports the rotary shaft 10. A seal member 12 for maintaining airtightness in the processing chamber 1 is provided between the periphery of the lid 9 and the lower end of the processing chamber 1.

The rotary shaft 10 is attached to the tip of an arm 13 supported by an elevator mechanism (not illustrated) such as a boat elevator. The boat 5 and the lid 9 are raised and lowered integrally, and are inserted into and removed from the processing chamber 1. The table 8 may be fixed to the side of the lid 9, and the substrates W may be processed without rotating the boat 5.

The film forming apparatus 100 includes a gas supply 20. The gas supply 20 supplies various gases used in the above-described film forming method into the processing chamber 1.

The gas supply 20 includes gas supply pipes 21 to 23. The gas supply pipes 21 and 22 are formed of, for example, quartz. The gas supply pipes 21 and 22 penetrate inward through the side wall of a manifold 3, are bent upward, and extend vertically. The upper ends of the vertical portions of the gas supply pipes 21 and 22 are closed. In the vertical portions of the gas supply pipes 21 and 22, a plurality of gas holes 21g and a plurality of gas holes 22g are formed at predetermined intervals over a vertical length corresponding to the substrate support range of the boat 5. The gas holes 21g and 22g discharge gases in the horizontal direction. The gas supply pipe 23 includes a plurality of gas supply pipes 23 (n gas supply pipes 23, where n is a natural number greater than or equal to 2. In FIG. 8, only two gas supply pipes 23 are illustrated and the others are omitted.). The gas supply pipes 23 have different heights. The gas supply pipes 23 are formed of, for example, quartz, and penetrate inward through the side wall of the processing chamber 1, are bent upward, and extend vertically. The upper ends of the vertical portions of the gas supply pipes 23 are open and discharge supplied gases. In the vertical portions of the gas supply pipes 23 having different heights, a plurality of gas holes (not illustrated) may be formed at predetermined intervals in the side walls of portions of the gas supply pipes 23 where there is a height difference.

The vertical portion of the gas supply pipe 21 (the vertical portion in which the gas holes 21g are formed) is provided in the processing chamber 1. A fluorine-containing gas is supplied to the gas supply pipe 21 from a gas source 21a via a gas pipe 21d. The fluorine-containing gas is, for example, hydrogen fluoride gas. The gas pipe 21d is provided with a flow controller 21b and an opening/closing valve 21c. Thus, the fluorine-containing gas from the gas source 21a is supplied into the processing chamber 1 via the gas pipe 21d and the gas supply pipe 21.

The vertical portion of the gas supply pipe 22 (the vertical portion in which the gas holes 22g are formed) is provided in the processing chamber 1. A basic gas is supplied to the gas supply pipe 22 from a gas source 22a via a gas pipe 22d. The basic gas is, for example, ammonia gas. The gas pipe 22d is provided with a flow controller 22b and an opening/closing valve 22c. Thus, the basic gas from the gas source 22a is supplied into the processing chamber 1 via the gas pipe 22d and the gas supply pipe 22.

The vertical portions of the gas supply pipes 23 are provided in the processing chamber 1. A gas source 23a1, a gas source 23a2, and a gas source 23a3 are connected to the gas supply pipes 23 via branching gas pipes 23d1, 23d2, and 23d3.

The gas source 23a1 supplies a silicon-containing gas to the gas supply pipes 23. The silicon-containing gas is, for example, monosilane gas. The gas pipe 23d1, which is branched and connected to the gas source 23a1, is provided with a flow controller 23b1 and an opening/closing valve 23c1. The flow controller 23b1 and the opening/closing valve 23c1 are provided for each of the plurality of gas supply pipes 23. Thus, the silicon-containing gas from the gas source 23a1 is supplied into the processing chamber 1 via the gas pipe 23d1 and the gas supply pipes 23.

The gas source 23a2 supplies a germanium-containing gas to the gas supply pipes 23. The germanium-containing gas is, for example, monogermane gas. The gas pipe 23d2, which is branched and connected to the gas source 23a2, is provided with a flow controller 23b2 and an opening/closing valve 23c2. The flow controller 23b2 and the opening/closing valve 23c2 are provided for each of the plurality of gas supply pipes 23. Thus, the germanium-containing gas from the gas source 23a2 is supplied into the processing chamber 1 via the gas pipe 23d2 and the gas supply pipes 23.

The gas source 23a3 supplies a reducing gas to the gas supply pipes 23. The reducing gas is, for example, hydrogen gas. The gas pipe 23d3, which is branched and connected to the gas source 23a3, is provided with a flow controller 23b3 and an opening/closing valve 23c3. The flow controller 23b3 and the opening/closing valve 23c3 are provided for each of the plurality of gas supply pipes 23. Thus, the reducing gas from the gas source 23a3 is supplied into the processing chamber 1 via the gas pipe 23d3 and the gas supply pipes 23.

A purge gas is supplied to each of the gas supply pipes 21 to 23 from a purge gas source (not illustrated) via a gas pipe. The gas pipe is provided with a flow controller (not illustrated) and an opening/closing valve (not illustrated). Thus, the purge gas from the purge gas source is supplied into the processing chamber 1 via the gas pipe and the gas supply pipes 21 to 23. As the purge gas, for example, an inert gas such as nitrogen (N₂) gas or argon (Ar) gas can be used.

An exhaust port 41 for evacuating the inside of the processing chamber 1 to a vacuum is provided on a side wall portion of the processing chamber 1 facing a position where the gas supply pipes 21 to 23 are disposed. The exhaust port 41 is formed on a lower side wall portion of the processing chamber 1. An exhaust pipe 42 for evacuating the processing chamber 1 is connected to the exhaust port 41. An exhaust device 44 including a pressure control valve 43 for controlling the pressure in the processing chamber 1, a vacuum pump, and the like is connected to the exhaust pipe 42, and the inside of the processing chamber 1 is evacuated via the exhaust pipe 42 by the exhaust device 44.

The film forming apparatus 100 includes a heater 50. The heater 50 has a cylindrical shape and is provided so as to surround the outer periphery of the processing chamber 1. The heater 50 heats the processing chamber 1 and the substrates W inside the processing chamber 1.

The film forming apparatus 100 includes a controller 60. The controller 60 controls the operation of each part of the film forming apparatus 100. For example, the controller 60 controls the supply and the stop of each gas by opening and closing each of the opening/closing valves 21c, 22c, and 23c1 to 23c3, controls the gas flow rates by the flow controllers 21b, 22b, and 23b1 to 23b3, controls the pressure by the pressure control valve 43, and controls the exhaust by the exhaust device 44. For example, the controller 60 controls the temperature of the substrates W by the heater 50.

The controller 60 is an electronic circuit such as a central processing unit (CPU), a field programmable gate array (FPGA), or an application specific integrated circuit (ASIC). The controller 60 performs various control operations described in the present specification by executing instruction codes stored in a memory or by being designed as a circuit for a special application.

### Operation of Film Forming Apparatus

The operation of the film forming apparatus 100 when the film forming apparatus 100 performs the film forming method according to the embodiment will be described. The operation of the film forming apparatus 100 described below is performed as controlled by the controller 60.

First, the elevator mechanism loads the boat 5 holding the plurality of substrates W into the processing chamber 1, and the lid 9 closes the opening at the lower end of the processing chamber 1 to seal the processing chamber 1 airtight. Then, the exhaust device 44 depressurizes the inside of the processing chamber 1, and the heater 50 adjusts the temperature of the substrates W to a predetermined temperature. Each of the substrates W may be the substrate 200 described above.

Next, the controller 60 controls the operation of each part of the film forming apparatus 100 to perform steps S2 to S6 of the film forming method according to the embodiment in this order.

Next, the controller 60 increases the pressure inside the processing chamber 1 to the atmospheric pressure and decreases the temperature inside the processing chamber 1 to an unloading temperature, and then controls the elevator mechanism to unload the boat 5 from the processing chamber 1.

### Experimental Results

In an example, a silicon substrate was accommodated in the processing chamber 1 of the film forming apparatus 100, and a silicon germanium film, a first silicon film, and a second silicon film were formed on the silicon substrate in this order by performing steps S2 to S6 in the processing chamber 1. In step S2, the heat treatment temperature T0 was controlled at 800°C or higher and 900°C or lower, and hydrogen gas was used as the reducing gas. In step S3, the first temperature T1 was controlled at 480°C, monosilane gas was used as the first silicon-containing gas, and monogermane gas was used as the germanium-containing gas. In step S4, the first temperature T1 was controlled at 480°C, and monosilane gas was used as the second silicon-containing gas. In step S6, the second temperature T2 was controlled at 650°C, and monosilane gas was used as the third silicon-containing gas.

In a comparative example, a silicon substrate was accommodated in the processing chamber 1 of the film forming apparatus 100, and a silicon germanium film and a second silicon film were formed in this order on the silicon substrate by performing step S2, step S3, step S5, and step S6 in this order in the processing chamber 1. The conditions of step S2, step S3, step S5, and step S6 were the same as those of the example.

Next, the cross-sectional structure of the films formed in the example and the cross-sectional structure of the films formed in the comparative example were evaluated by high-angle annular dark-field scanning transmission electron microscopy (HAADF-STEM).

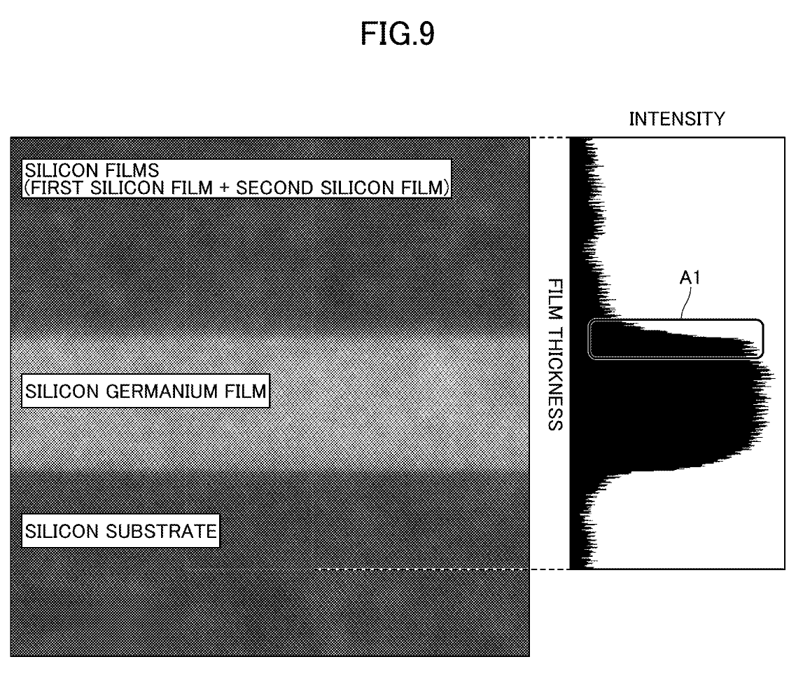

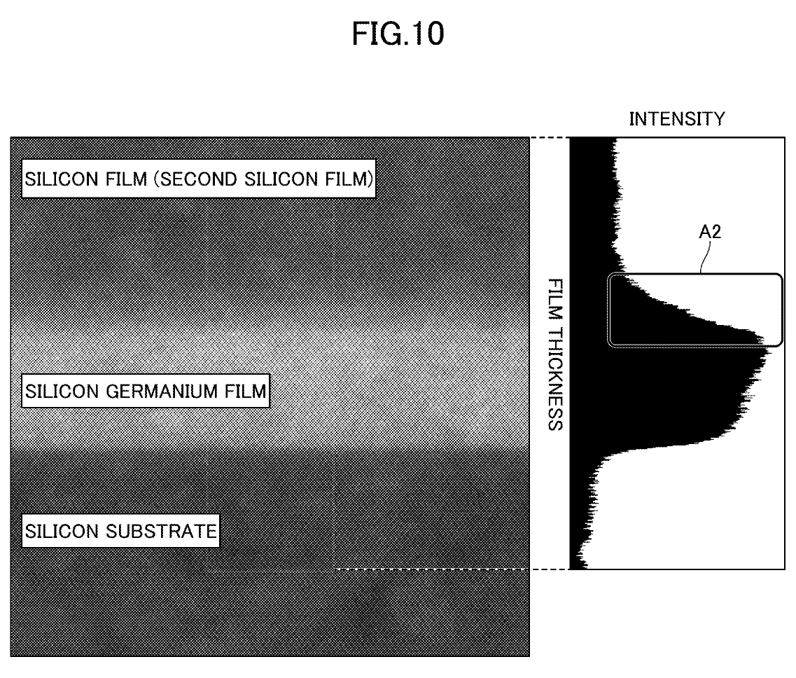

FIG. 9 is a diagram illustrating results of the example. FIG. 10 is a diagram illustrating results of the comparative example. FIG. 9 and FIG. 10 illustrate HAADF-STEM images on the left and the intensity of the HAADF-STEM images on the right. In the HAADF-STEM images, heavier elements appear brighter. Because germanium is a heavier element than silicon, germanium appears brighter in the HAADF-STEM images.

As illustrated in FIG. 9, it can be seen that the intensity of the HAADF-STEM image changes sharply at the interface between the silicon germanium film and the silicon films (see a region A1) in the example. From this result, in the example, it is considered that segregation of germanium in the silicon germanium film at the interface between the silicon germanium film and the silicon films is suppressed.

As illustrated in FIG. 10, it can be seen that the intensity of the HAADF-STEM image changes gradually at the interface between the silicon germanium film and the silicon film (see a region A2) in the comparative example. From this result, in the comparative example, it is considered that germanium in the silicon germanium film is segregated at the interface between the silicon germanium film and the silicon film.

While certain embodiments have been described, these embodiments have been presented by way of example only, and are not intended to limit the scope of the present disclosure. Indeed, the embodiments described herein may be embodied in a variety of other forms. Furthermore, various omissions, substitutions and changes in the form of the embodiments described herein may be made without departing from the spirit of the present disclosure.

In the above-described embodiments, an example in which the first silicon-containing gas, the second silicon-containing gas, and the third silicon-containing gas are monosilane (SiH₄) gas has been described; however, the present disclosure is not limited thereto. For example, the first silicon-containing gas, the second silicon-containing gas, and the third silicon-containing gas may be SiH₄ gas, Si₂H₆ gas, dichlorosilane gas, or a combination thereof. The first silicon-containing gas, the second silicon-containing gas, and the third silicon-containing gas may be different types of gases.

In the above-described embodiments, an example in which the germanium-containing gas is monogermane (GeH₄) gas has been described, but the present disclosure is not limited thereto. The germanium-containing gas may be GeH₄ gas, Ge₂H₆ gas, Ge₃H₈ gas, or a combination thereof.

In the above-described embodiments, an example in which the film forming apparatus is a batch-type apparatus configured to process a plurality of substrates at one time has been described; however, the present disclosure is not limited thereto. For example, the film forming apparatus may be a single-wafer type apparatus configured to process substrates one by one. For example, the film forming apparatus may be a semi-batch-type apparatus configured to process a plurality of substrates disposed on a rotation table by rotating the rotation table to allow each of the substrates to revolve and repeatedly pass through processing gas supply regions disposed along the radius direction of the rotation table.

According to an embodiment of the present disclosure, segregation of germanium when a silicon film is formed on a silicon germanium film can be suppressed.

What is claimed is:

1. A film forming method comprising:
forming a silicon germanium film on a substrate by supplying a first silicon-containing gas and a germanium-containing gas to the substrate while heating the substrate at a first temperature;
forming a first silicon film on the silicon germanium film by supplying a second silicon-containing gas to the substrate while heating the substrate at the first temperature;
increasing a temperature of the substrate from the first temperature to a second temperature higher than the first temperature; and
forming a second silicon film on the first silicon film by supplying a third silicon-containing gas to the substrate while heating the substrate at the second temperature.

2. The film forming method according to claim 1, wherein the silicon germanium film is formed by epitaxial growth.

3. The film forming method according to claim 1, wherein a thickness of the first silicon film is 1 nm or less.

4. The film forming method according to claim 1, further comprising:
repeating the forming of the silicon germanium film, the forming of the first silicon film, and the forming of the second silicon film in this order.

5. The film forming method according to claim 1, wherein the first silicon-containing gas, the second silicon-containing gas, and the third silicon-containing gas are the same gas.

6. The film forming method according to claim 1, wherein the first temperature is in a range of 400ºC or higher and 600ºC or lower.

7. The film forming method according to claim 1, wherein the second temperature is in a range of 600ºC or higher and 700ºC or lower.

8. The film forming method according to claim 1, further comprising:
before the forming of the silicon germanium film, removing a native oxide film at a surface of the substrate by supplying a reducing gas to the substrate while heating the substrate at a third temperature higher than the second temperature.

9. The film forming method according to claim 8, wherein the third temperature is in a range of 800ºC or higher and 900ºC or lower.

10. The film forming method according to claim 1, further comprising:
before the forming of the silicon germanium film, removing a native oxide film at a surface of the substrate by supplying a fluorine-containing gas and a basic gas to the substrate.

11. A film forming apparatus comprising:
a processor; and
a controller, wherein
the controller is configured to control the processor to execute:
forming a silicon germanium film on a substrate by supplying a first silicon-containing gas and a germanium-containing gas to the substrate while heating the substrate at a first temperature;
forming a first silicon film on the silicon germanium film by supplying a second silicon-containing gas to the substrate while heating the substrate at the first temperature;
increasing a temperature of the substrate from the first temperature to a second temperature higher than the first temperature; and
forming a second silicon film on the first silicon film by supplying a third silicon-containing gas to the substrate while heating the substrate at the second temperature.
